(19) United States
(12) Patent Application Publication
(10) Pub. No.: US 2025/0133852 A1
(43) Pub. Date: Apr. 24, 2025

(54) PHOTOELECTRIC SENSOR AND FORMING METHOD THEREOF

(71) Applicants: Semiconductor Manufacturing International (Beijing) Corporation, Beijing (CN); Semiconductor Manufacturing International (Shanghai) Corporation, Shanghai (CN)

(72) Inventors: Huike WANG, Beijing (CN); Zhigao WANG, Beijing (CN)

(21) Appl. No.: 18/917,605

(22) Filed: Oct. 16, 2024

(30) Foreign Application Priority Data
Oct. 19, 2023 (CN) 202311360499.2

(51) Int. Cl. H01L 27/146

(52) U.S. Cl. CPC H10F 39/806; H10F 39/024; H10F 39/199; H10F 39/8057; H10F 39/809

(57) ABSTRACT

The present disclosure discloses a photoelectric sensor and a forming method thereof. The photoelectric sensor includes a substrate and a light-transmitting layer. The substrate has a light-receiving surface and includes a plurality of photosensitive pixel regions. Each photosensitive pixel region includes a plurality of pixel units arranged in a matrix. In a pixel unit, a plurality of first protrusions are formed in the light-receiving surface of the substrate, and both a lateral dimension and a vertical dimension of a first protrusion of the plurality of first protrusions are smaller than a wavelength of light. The light-transmitting layer covering the light-receiving surface of the substrate and filling between adjacent first protrusions of the plurality of first protrusions.

### CROSS-REFERENCES TO RELATED APPLICATIONS

The present disclosure claims priority to Chinese Patent Application No. 202311360499.2, filed on Oct. 19, 2023, the content of which is incorporated herein by reference in its entirety.

### FIELD OF THE DISCLOSURE

The present disclosure relates to the field of semiconductor manufacturing and, more specifically, relates to a photoelectric sensor and a forming method thereof.

### BACKGROUND

A photoelectric sensor is a device that converts optical signals into electrical signals. Its working principle is based on the photoelectric effect, which occurs when electrons in certain materials absorb the energy of photons upon exposure to light, resulting in corresponding electrical effects.

For example, CCD (Charge Coupled Device) image sensors and CMOS image sensors utilize the photoelectric conversion function to convert optical images into electrical signals and then output digital images. These sensors are currently widely used in digital cameras and other electronic optical devices. ToF (Time of Flight) distance sensors project a modulated infrared light source onto objects, people, or scenes, and then the reflected light is captured by ToF sensors. The sensor measures the light intensity and phase difference received by a pixel, thereby obtaining highly reliable depth images and grayscale images of the entire scene. This technology finds applications in various distance measurement scenarios such as autonomous driving, robotic vacuum cleaners, and VR (Virtual Reality)/AR (Augmented Reality) modeling, etc.

Photoelectric sensors typically have a pixel region of a certain area for receiving optical signals. The higher the optical transmittance of the pixel region, the better the optical sensitivity performance of the device. However, the current photosensitivity performance of photoelectric sensors needs improvement.

### BRIEF SUMMARY OF THE DISCLOSURE

One aspect of the present disclosure provides a photoelectric sensor. The photoelectric sensor includes a substrate and a light-transmitting layer. The substrate has a light-receiving surface and includes a plurality of photosensitive pixel regions. Each photosensitive pixel region includes a plurality of pixel units arranged in a matrix. In a pixel unit, a plurality of first protrusions are formed in the light-receiving surface of the substrate, and both a lateral dimension and a vertical dimension of a first protrusion of the plurality of first protrusions are smaller than a wavelength of light. The light-transmitting layer covering the light-receiving surface of the substrate and filling between adjacent first protrusions of the plurality of first protrusions.

Another aspect of the present disclosure provides a method for forming a photoelectric sensor. The method includes providing a substrate. The substrate has a light-receiving surface and includes a plurality of photosensitive pixel regions. Each photosensitive pixel region includes a plurality of pixel units arranged in a matrix. The method also includes forming a plurality of first protrusions in the light-receiving surface of the substrate in a pixel unit of the plurality of pixel units, where both a lateral dimension and a vertical dimension of a first protrusion of the plurality of first protrusions are smaller than a wavelength of light. The method further includes forming a light-transmitting layer covering the light-receiving surface of the substrate, where the light-transmitting layer fills between adjacent first protrusions of the plurality of first protrusions.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram corresponding to a photoelectric sensor;

FIGS. 2-3 illustrate schematic structural diagrams corresponding to a photoelectric sensor consistent with various disclosed embodiments in the present disclosure;

FIGS. 4-8 illustrate schematic structural diagrams corresponding to each step in a method for forming a photoelectric sensor consistent with various disclosed embodiments in the present disclosure; and

FIG. 9 illustrates a flowchart of an exemplary method for forming a photoelectric sensor consistent with various disclosed embodiments in the present disclosure.

### DETAILED DESCRIPTION

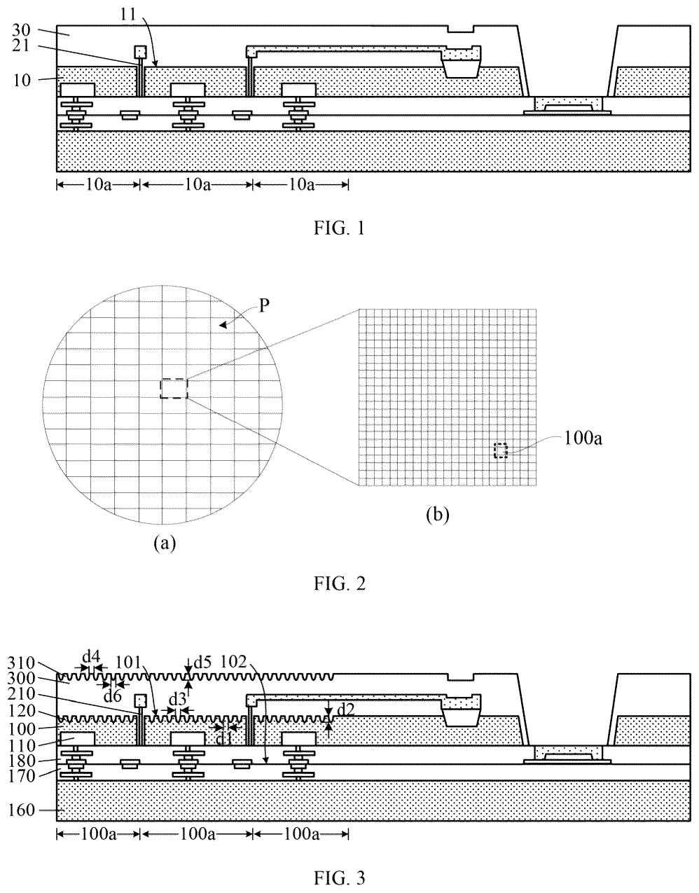

FIG. 1 illustrates a schematic structural diagram corresponding to a photoelectric sensor. Referring to FIG. 1, the photoelectric sensor includes a substrate 10, a light-transmitting layer 30 and a light-shielding structure 21. The substrate 10 has a light-receiving surface 11 and includes a plurality of photosensitive pixel regions, where each photosensitive pixel region includes a plurality of pixel units 10a arranged in a matrix. The light-transmitting layer 30 covers the light-receiving surface 11 of the substrate 10. The light-shielding structure 21 is located in the substrate 10 between adjacent pixel units 10a.

When light is irradiated onto the light-receiving surface 11, partial photon loss occurs due to reflection from the surface of the light-transmitting layer 30 and further reflection from the light-receiving surface 11 of the substrate 10. This results in a reduced number of photons entering the PN junction in the substrate 10, making it difficult to trigger avalanche breakdown. Consequently, the light transmission through the light-transmitting layer 30 and the substrate 10 is limited, which makes it challenging to increase light signal collection and thus improve photoelectric detection efficiency.

To address the above technical issues, the present disclosure provides a photoelectric sensor. The photoelectric sensor includes a substrate and a light-transmitting layer. The substrate has a light-receiving surface and includes a plurality of photosensitive pixel regions, where each photosensitive pixel region includes a plurality of pixel units arranged in a matrix. In the pixel unit, a plurality of first protrusions are formed in the light-receiving surface of the substrate, where both a lateral dimension and a vertical dimension of a first protrusion are smaller than a wavelength of light. The light-transmitting layer covers the light-receiving surface of the substrate and fills between adjacent first protrusions.

In the photoelectric sensor provided by the present disclosure, since both the lateral dimension and the vertical dimension of a first protrusion are smaller than the wavelength of light, there is almost no reflection of light by the first protrusions when light is irradiated onto the light-receiving surface. On the light-receiving surface, light is more likely to regard the first protrusions and the light-transmitting layer between adjacent first protrusions as the same substance, which helps to reduce the reflection loss of light and increase the transmission of light on the light-receiving surface. This effectively increases the number of transmitted photons, facilitates light signal collection, and thereby improves photoelectric detection efficiency.

In order to make the above objectives, features and advantages of the present disclosure more apparent and understandable, detailed descriptions of specific embodiments of the present disclosure will be provided below with reference to the accompanying drawings.

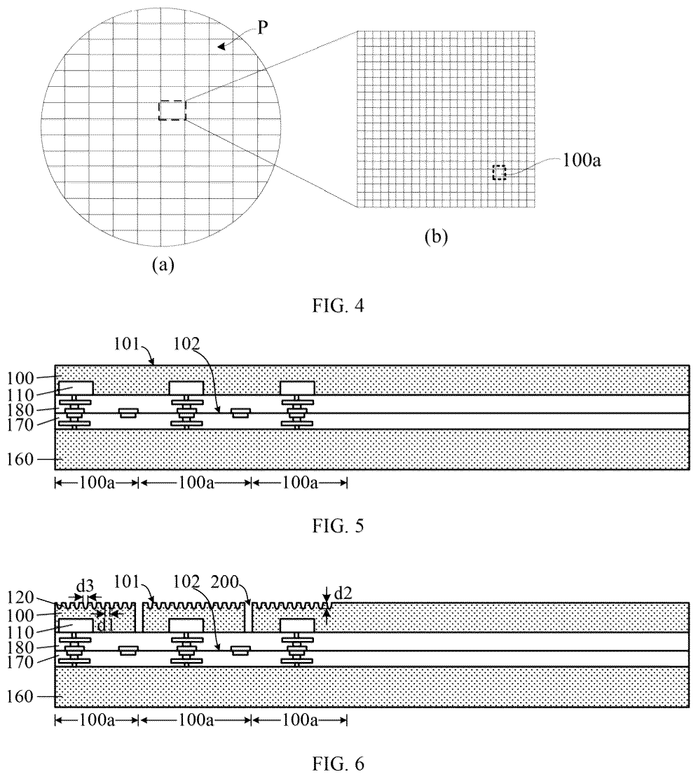

FIGS. 2-3 illustrate schematic structural diagrams corresponding to a photoelectric sensor consistent with various disclosed embodiments in the present disclosure.

Referring to FIGS. 2-3, FIG. 2(a) is a top view of the substrate, FIG. 2(b) is a partial enlarged view of any one photosensitive pixel region in FIG. 2(a), and FIG. 3 is a sectional view corresponding to FIG. 2(a). The photoelectric sensor includes a substrate 100 and a light-transmitting layer 300. The substrate 100 has a light-receiving surface 101 and includes a plurality of photosensitive pixel regions P. The photosensitive pixel region P includes a plurality of pixel units 100a arranged in a matrix. In the pixel unit 100a, a plurality of first protrusions 120 are formed in the light-receiving surface 101 of the substrate 100, where both a lateral dimension d1 and a vertical dimension d2 of a first protrusion 120 are smaller than a wavelength of light. The light-transmitting layer 300 covers the light-receiving surface 101 of the substrate 100 and fills space between adjacent first protrusions 120.

As an example, in one embodiment, the photoelectric sensor is configured as an example of a DTOF (Direct Time of Flight) sensor for illustration purposes.

In other embodiments, the photoelectric sensor may also include CCD (Charge Coupled Device) image sensors, CMOS image sensors, or iTOF (indirect Time of Flight) sensors, etc.

In one embodiment, the photoelectric sensor includes a logic wafer and a pixel wafer bonded to the logic wafer. The substrate 100 is located on the side of the pixel wafer facing away from the logic wafer, and the light-receiving surface 101 is the surface of the pixel wafer facing away from the logic wafer.

In one embodiment, the substrate 100 of the pixel wafer is a silicon substrate. In other embodiments, the material of the substrate of the pixel wafer may also include other materials such as germanium, silicon germanium, silicon carbide, gallium arsenide or indium gallium, etc.; and the substrate of the pixel wafer may also include other types of materials such as a silicon-on-insulator substrate or a germanium-on-insulator substrate, etc.

The photosensitive pixel region P is configured to receive optical signals in order to convert the optical signals into electrical signals.

In the pixel wafer, there are a plurality of photosensitive pixel regions P, and the plurality of photosensitive pixel regions P are arranged in a matrix. The pixel units 100a are configured to form pixels.

In one embodiment, the pixel wafer has the light-receiving surface 101. Where, the light-receiving surface 101 refers to the surface configured to receive light.

In one embodiment, the light-receiving surface 101 is a first surface; the pixel wafer also includes a second surface 102 opposite to the first surface.

In one embodiment, the photoelectric sensor is a backside illumination (BSI) photoelectric sensor.

Correspondingly, in one embodiment, the pixel wafer is a backside illumination pixel wafer. The light-receiving surface 101 corresponds to the backside, and the second surface 102 corresponds to the front.

In one embodiment, only a portion of the photosensitive pixel region P and the pixel units 100a are shown in the figure. The pixel units 100a may also include device structures such as photoelectric elements (e.g., photodiodes), etc. Where, the photodiode may be a backside illumination single photon avalanche diode (SPAD). For the purpose of simplification, detailed structures of the above components are not shown in one embodiment of the present disclosure.

In one embodiment, the logic wafer is bonded to the second surface 102 of the pixel wafer. The logic wafer is configured to analyze and process the electrical signals provided by the pixel wafer.

By setting the photosensitive pixel region P and the logic region on two separate wafers, and bonding the pixel wafer to the logic wafer, a larger pixel area may be obtained, and it is beneficial for shortening the path of light to reach the photoelectric element, reducing light scattering, focusing the light more, and thereby enhancing the photosensitivity of the photoelectric sensor in low-light environments and reducing system noise and crosstalk.

In one embodiment, the substrate 100 of the pixel wafer serves as a first substrate, and the logic wafer has a second substrate 160. The second substrate 160 of the logic wafer may be a silicon substrate. In other embodiments, the material of the second substrate of the logic wafer may also be germanium, silicon germanium, silicon carbide, gallium arsenide, or indium gallium, etc. The second substrate of the logic wafer may also be other types of materials, such as a silicon-on-insulator substrate or a germanium-on-insulator substrate, etc.

Correspondingly, in one embodiment, logic transistors (not shown in the figure) are also formed in the logic wafer, and the logic transistors are configured to perform logical processing on the electrical signals provided by the pixel wafer. Specifically, the logic transistors may include a logic gate structure located on the logic wafer, as well as a logic drain region and a logic source region respectively located on either side of the logic gate structure in the logic wafer.

In some embodiments, bonding between the second surface 102 of the pixel wafer and the logic wafer is achieved through hybrid bonding.

Specifically, in one embodiment, a first interconnect layer 180 is formed on the second surface 102 of the pixel wafer, and a second interconnect layer 170 is formed on the second substrate 160 of the logic wafer. The pixel wafer and the logic wafer may be joined together using dielectric bonding, followed by electrical connection between the first interconnect layer 180 and the second interconnect layer 170.

The first interconnect layer 180 may include a first metal line, or the first interconnect layer 180 may include a first through-silicon via interconnect structure (TSV), or the first interconnect layer 180 may include a first via interconnect structure and a first metal line located on the first via interconnect structure. The second interconnect layer 170 may include a second metal line, or the second interconnect layer 170 may include a second through-silicon via interconnect structure (TSV), or the second interconnect layer 170 may include a second via interconnect structure and a second metal line located on the second via interconnect structure.

It should be noted that the bonding method between the pixel wafer and the logic wafer described above is merely an example. The bonding method between the pixel wafer and the logic wafer is not limited thereto. For example, in other embodiments, the bonding method between the pixel wafer and the logic wafer may also include direct bonding techniques (such as fusion bonding and anodic bonding) or indirect bonding techniques (such as metal eutectic bonding, thermocompression bonding, and adhesive bonding), etc.

The first protrusions 120 are arranged in the pixel unit 100a, which may improve the optical transmittance of the photosensitive pixel region P and increase the photoelectric conversion efficiency, thereby enhancing the optical sensitivity performance of the photoelectric sensor.

Specifically, the first protrusions 120 are positioned above the photoelectric element, and grooves are formed between adjacent first protrusions of the plurality of first protrusions 120, which may mitigate the refractive index change between the air and the light-receiving surface 101, reduce the high reflectivity caused by the abrupt refractive index change at the interface, thereby allowing more light to enter the photoelectric element and increasing the transmittance of incident light. Moreover, by setting the first protrusions 120 in the plurality of pixel units 100a in the light-receiving surface 101, it may disperse the incident light to multiple angles, thereby increasing the effective optical path length of the light and effectively serving to trap light.

In one embodiment, since both the lateral dimension d1 and the vertical dimension d2 of the first protrusion 120 are smaller than the wavelength of light, the first protrusions 120 reflects almost no light when light is irradiated onto the light-receiving surface 101. On the light-receiving surface 101, light is likely to regard the first protrusions 120 and the light-transmitting layer 300 between adjacent first protrusions 120 as the same substance, which may reduce light reflection loss, increase the light transmission on the light-receiving surface 101, effectively increase the number of transmitted photons and facilitate light signal collection, thus improving the photoelectric detection efficiency.

Both the lateral dimension d1 and the vertical dimension d2 of the first protrusion 120 are smaller than the wavelength of light, which means that both the lateral dimension dl and the vertical dimension d2 of the first protrusion 120 are smaller than the wavelength of light used in the photoelectric sensor during operation in one embodiment. The wavelength of light refers to the distance that the light wave travels within one oscillation cycle. Therefore, when both the lateral dimension d1 and the vertical dimension d2 of the first protrusion 120 are smaller than the wavelength of light, the first protrusions 120 may hardly reflect the light, thereby reducing reflection loss of light.

In one embodiment, a spacing d3 between adjacent first protrusions 120 in the pixel unit 100a is smaller than the wavelength of light.

Since the spacing d3 between adjacent first protrusions 120 is smaller than the wavelength of light, the light-transmitting layer 300 between adjacent first protrusions 120 reflects almost no light when light is irradiated onto the light-receiving surface 101. On the light-receiving surface 101, light is more likely to regard the first protrusions 120 and the light-transmitting layer 300 between adjacent first protrusions 120 as the same substance, which may facilitate a reduction in light reflection loss, promote an increase in light transmission on the light-receiving surface 101, effectively increase the number of transmitted photons and facilitate light signal collection, thereby enhancing the photoelectric detection efficiency.

In one embodiment, the lateral dimensions dl of the first protrusion 120 gradually increase from top to bottom.

Since the lateral dimensions d1 of the first protrusion 120 gradually increase from top to bottom, the film layer formed by the first protrusions 120 and the light-transmitting layer 300 between adjacent first protrusions 120 may be regarded as a layer-by-layer thin film with a gradually changing refractive index. This results in a gradual change in the refractive index when light passes through the light-receiving surface 101 into the substrate 100, significantly reducing the high reflectivity caused by abrupt changes in the refractive index at the interface. Consequently, more light enters the photoelectric elements, increasing the transmittance of incident light and enhancing the anti-reflection effect.

In one embodiment, a shape of the first protrusion 120 is not limited. Specifically, as an example, the shape of the first protrusion 120 in one embodiment may include a cylinder, a truncated cone, a prism, or a cuboid.

In one embodiment, within the pixel unit 100a, the plurality of first protrusions 120 are arranged in an array.

The plurality of first protrusions 120 are arranged in an array within the pixel unit 100a, which not only facilitates the design and layout but also maximizes the number of first protrusions 120 in a single pixel unit 100a. This further increases the density of the first protrusions 120, enhancing the uniformity of the film layer formed by the first protrusions 120 and the light-transmitting layer 300 between adjacent first protrusions 120.

In other embodiments, within the pixel unit, the first protrusions may not be arranged in an array. The first protrusions in the pixel unit may adopt other arrangements, such as scattered arrangement, staggered arrangement, or grid-like connection, etc.

The light-transmitting layer 300 has light-transmitting properties. The light-transmitting layer 300 is formed on the light-receiving surface 101, allowing light to pass through the light-transmitting layer 300 and enter the light-receiving surface 101 and the substrate 100 below it, thus enabling the photoelectric elements to function properly.

In one embodiment, the light-transmitting layer 300 is made of a light-transmitting material, and the material of the light-transmitting layer 300 is an insulating material to prevent any impact on the electrical performance of the photoelectric sensor. In one embodiment, the material of the light-transmitting layer 300 includes silicon dioxide, silicon nitride, silicon oxynitride, or silicon carbide. As an example, the material of the light-transmitting layer 300 may be silicon dioxide. Silicon dioxide has high process compatibility, low cost, excellent light-transmitting and insulating properties.

In one embodiment, a plurality of second protrusions 310 are formed over the light-transmitting layer 300, and both a lateral dimension d4 and a vertical dimension d5 of a second protrusion 310 are smaller than the wavelength of light.

The second protrusions 310 may improve the optical transmittance of the photosensitive pixel region P and increase the photoelectric conversion efficiency, thereby enhancing the optical sensitivity performance of the photoelectric sensor. Additionally, the plurality of second protrusions 310 arranged on the surface of the light-transmitting layer 300 also have a repellent effect on water, thereby helping to avoid condensation of moisture on the surface of the light-transmitting layer 300 as much as possible.

Specifically, the second protrusions 310 are positioned above the photoelectric elements, and grooves are formed between adjacent second protrusions 310. This may mitigate the refractive index change between air and the surface of the light-transmitting layer 300, and reduce the high reflectivity caused by the abrupt refractive index change at the interface, thereby allowing more light to enter the light-transmitting layer 300 and increasing the transmittance of incident light.

In one embodiment, since both the lateral dimension d4 and the vertical dimension d5 of the second protrusion 310 are smaller than the wavelength of light, the second protrusions 310 reflects almost no light when light is irradiated onto the surface of the light-transmitting layer 300. On the surface of the light-transmitting layer 300, light is more likely to regard the second protrusions 310 and the light-transmitting layer 300 between adjacent second protrusions 310 as the same substance. This may facilitate a reduction in light reflection loss, promote an increase in light transmission on the surface of the light-transmitting layer 300, effectively increase the number of transmitted photons and facilitate light signal collection, thereby enhancing the photoelectric detection efficiency.

In one embodiment, a spacing d6 between adjacent second protrusions 310 is smaller than the wavelength of light.

Since the spacing d6 between adjacent second protrusions 310 is smaller than the wavelength of light, when the light is irradiated on the light-transmitting layer 300, light is more likely to regard the second protrusions 310 and the air between adjacent second protrusions 310 as the same substance. This may facilitate a reduction in light reflection loss, promote an increase in light transmission on the surface of the light-transmitting layer 300, effectively increase the number of transmitted photons and facilitate light signal collection, thereby enhancing the photoelectric detection efficiency.

In one embodiment, the lateral dimensions d4 of a second protrusion 310 gradually increase from top to bottom.

Since the lateral dimensions d4 of the second protrusion 310 gradually increase from top to bottom, the second protrusions 310 and the air between adjacent second protrusions 310 may be regarded as a layer-by-layer thin film with a gradually changing refractive index, allowing for a smooth gradient of refractive index change when light enters the light-transmitting layer 300. This greatly reduces the high reflectivity caused by the abrupt refractive index change at the interface, allowing more light to enter the photoelectric element, thus increasing the transmittance of incident light and providing an anti-reflection effect.

In one embodiment, the shape of the second protrusion 310 is not limited. Specifically, as an example, the shape of the second protrusion 310 in one embodiment includes a cylinder, a truncated cone, a prism, or a cuboid.

In one embodiment, the plurality of second protrusions 310 are arranged in an array.

The arrayed arrangement of the plurality of second protrusions 310 is not only advantageous for layout and design but also facilitates maximizing the number of the second protrusions 310, thereby further increasing the density of the second protrusions 310 and improving the uniformity of the film layer formed by the second protrusions 310 and air between adjacent second protrusions 310.

In other embodiments, the second protrusions may not be arranged in an array, and may be arranged in other ways, for example, a scattered arrangement, a staggered arrangement, or grid-like interconnected arrangements, etc.

In one embodiment, the photoelectric sensor further includes a doping region 110 located in the substrate 100 of the pixel unit 100a.

During the operation of the photoelectric sensor, the generated electrons move towards the doping region 110. And the doping region 110, as a type doping region, is configured to accumulate electrons during the photoelectric conversion process.

Specifically, in one embodiment, the doping type of the doping region 110 is N-type, and the doping ions of the N-type doping region include P ions, As ions, or Sb ions.

The N-type doping region is connected to a high potential during the operation of the photoelectric sensor. The carriers in the N-type doping region are electrons, and the concentration of free electrons is much greater than the concentration of holes. Therefore, the N-type doping region is an area for accumulating electrons.

As the primary region for generating and storing photo-generated carriers, the N-type doping region is located below the first protrusions 120. The first protrusions 120 above the N-type doping region effectively increase the efficiency of photo-generated carrier generation, thereby improving the performance of the photoelectric sensor.

In one embodiment, the photoelectric sensor further includes a light-shielding structure 210 located in the substrate 100 between adjacent pixel units 100a.

The light-shielding structure 210 is configured to prevent optical crosstalk between adjacent pixels.

Specifically, the light-shielding structure 210 has a blocking effect on light. Since the light-shielding structure 210 is positioned in the light-transmitting layer 300 between adjacent pixel units 100a, when incident light irradiates on the photosensitive pixel region P, the incident light only enters the corresponding pixel unit 100a through the light-transmitting layer 300. The incident light is unable to pass through the light-shielding structure 210 surrounding the light-transmitting layer 300 to reach adjacent pixel units 100a, thereby avoiding optical crosstalk with other pixel units 100a.

In one embodiment, the material of the light-shielding structure 210 is conductive. Conductive materials are typically opaque, thus fulfilling the light-shielding function of the light-shielding structure 210.

As an example, the conductive material may be a metal material. Specifically, the material of the light-shielding structure 210 may include one or more of W, Al, Cu, Ti, TiN, Ta and TaN. In one embodiment, the material of the light-shielding structure 210 is W.

In other embodiments, the conductive material may also be polysilicon doped with conductive ions.

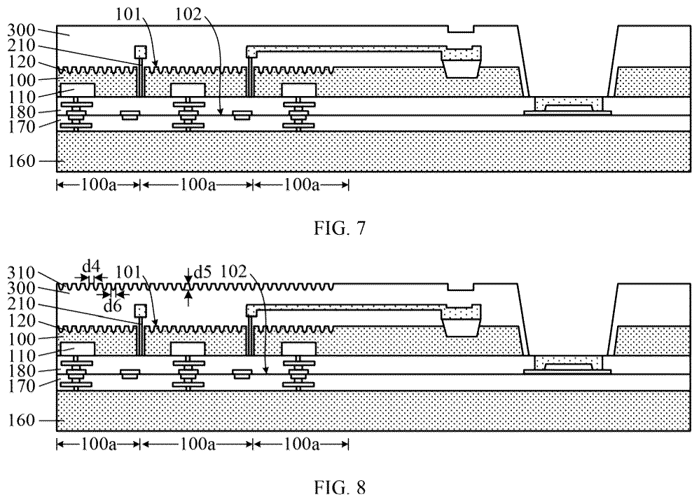

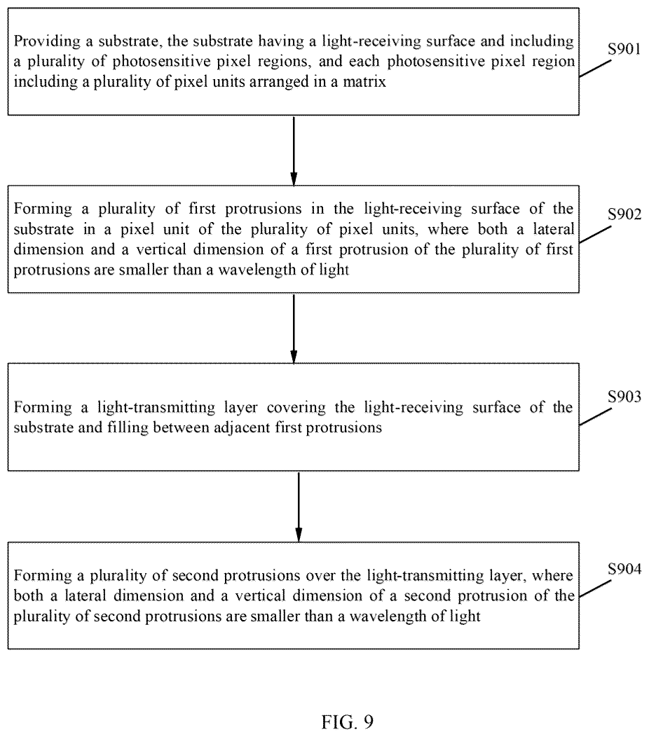

The present disclosure provides a method for forming a photoelectric sensor. FIG. 9 illustrates a flowchart of an exemplary method for forming a photoelectric sensor consistent with various disclosed embodiments in the present disclosure. FIGS. 4-8 illustrate schematic structures corresponding to steps of an exemplary method for forming a photoelectric sensor according to the present disclosure.

Referring to FIG. 9, at the beginning of the forming process, a substrate is provided (S901). FIGS. 4-5 show a schematic structure of a corresponding substrate.

Referring to FIGS. 4-5, a substrate is provided. FIG. 4(a) shows a top view of a substrate, FIG. 4(b) depicts a partial enlarged view of any one photosensitive pixel region in FIG. 4(a), and FIG. 5 provides a cross-sectional view corresponding to FIG. 4(a), presenting a substrate 100. The substrate 100 has a light-receiving surface 101 and includes a plurality of photosensitive pixel regions P, and each photosensitive pixel region P includes a plurality of pixel units 100a arranged in a matrix.

As an example, the present disclosure illustrates the photoelectric sensor as a DTOF (Direct Time of Flight) sensor.

In other embodiments, the photoelectric sensor may also be a CCD (Charge Coupled Device) image sensor, a CMOS image sensor, or an iTOF (indirect Time of Flight) sensor.

In one embodiment, the photoelectric sensor includes a logic wafer and a pixel wafer bonded to the logic wafer. The substrate 100 is positioned on the side of the pixel wafer facing away from the logic wafer, and the light-receiving surface 101 is the surface of the pixel wafer facing away from the logic wafer.

In one embodiment, the substrate 100 of the pixel wafer is a silicon substrate. In other embodiments, the substrate material of the pixel wafer may include germanium, silicon germanium, silicon carbide, gallium arsenide, or indium gallium arsenide, etc. The substrate of the pixel wafer may also be other type of material, such as a silicon-on-insulator substrate, or a germanium-on-insulator substrate, etc.

The photosensitive pixel region P is configured to receive optical signals and convert them into electrical signals.

In the pixel wafer, there are a plurality of photosensitive pixel regions P arranged in a matrix. The pixel units 100a are configured to form pixels.

In one embodiment, the pixel wafer has the light-receiving surface 101. The light-receiving surface 101 refers to the surface configured for receiving light.

In one embodiment, the light-receiving surface 101 is a first surface; and the pixel wafer also includes a second surface 102 opposite to the first surface.

In one embodiment, the photoelectric sensor is a backside illumination (BSI) photoelectric sensor.

Correspondingly, in one embodiment, the pixel wafer is a backside illumination pixel wafer, where the light-receiving surface 101 corresponds to the backside, and the second surface 102 corresponds to the front side.

In one embodiment, only a part of the photosensitive pixel region P and the pixel units 100a are shown in the figure. The pixel units 100a may also include photoelectric elements (e.g., photodiodes). The photodiode may be a backside illumination single photon avalanche diode (SPAD). For the purpose of simplification, the detailed structures of the above components are not shown in one embodiment of the present disclosure.

In one embodiment, the logic wafer is bonded to the second surface 102 of the pixel wafer.

The logic wafer is configured to analyze and process the electrical signals provided by the pixel wafer.

By arranging the photosensitive pixel region P and the logic region on two wafers respectively and bonding the pixel wafer and the logic wafer together, a larger pixel area may be obtained. This is beneficial for shortening the path of light reaching the photoelectric elements, reducing light scattering, focusing the light more, thereby enhancing the sensitivity of the photoelectric sensor in low-light environments, and reducing system noise and crosstalk.

In one embodiment, the substrate 100 of the pixel wafer serves as a first substrate, and the logic wafer includes a second substrate 160. The second substrate 160 of the logic wafer may be a silicon substrate. In other embodiments, the material of the second substrate of the logic wafer may also include other materials, such as germanium, silicon germanium, silicon carbide, gallium arsenide, or indium gallium, etc. The second substrate of the logic wafer may also include other types of materials, such as a silicon-on-insulator substrate or a germanium-on-insulator substrate, etc.

Correspondingly, in one embodiment, logic transistors (not shown in the figure) are also formed in the logic wafer. The logic transistors are configured to perform logic processing on the electrical signals provided by the pixel wafer. Specifically, the logic transistors may include logic gate structures located on the logic wafer, as well as a logic drain region and a logic source region respectively located on either side of the logic gate structure in the logic wafer.

As an embodiment, the bonding between the second surface 102 of the pixel wafer and the logic wafer is achieved through hybrid bonding.

Specifically, in one embodiment, a first interconnect layer 180 is formed on the second surface 102 of the pixel wafer, and a second interconnect layer 170 is formed on the second substrate 160 of the logic wafer. The pixel wafer and the logic wafer can be joined together using dielectric bonding, and then the first interconnection layer 180 and the second interconnection layer 170 are electrically connected.

The first interconnect layer 180 may include a first metal line, or the first interconnect layer 180 may include a first through-silicon via (TSV) interconnect structure, or the first interconnect layer 180 may include a first via interconnect structure and a first metal line located on the first via interconnect structure; the second interconnect layer 170 may include a second metal line, or the second interconnect layer 170 may include a second through-silicon via interconnect structure (TSV), or the second interconnect layer 170 may include a second via interconnect structure and a second metal line located on the second via interconnect structure.

It should be noted that the bonding method between the pixel wafer and the logic wafer described above is only one embodiment, and the bonding method between the pixel wafer and the logic wafer is not limited thereto. For example, in other embodiments, the bonding method between the pixel wafer and the logic wafer may also include direct bonding (such as fusion bonding and anodic bonding) or indirect bonding (such as metal eutectic bonding, thermocompression bonding, and adhesive bonding), etc.

In one embodiment, in the step of providing the substrate 100, a doping region 110 is also formed in the substrate 100, located in the substrate 100 in the pixel units 100a.

During the operation of the photoelectric sensor, generated electrons move toward the doping region 110, where the doping region 110 is configured to accumulate electrons in the process of photoelectric conversion.

Specifically, in one embodiment, the doping region 110 is of N-type doping, where the doping ions of the N-type doping region include N-type ions such as Pions, As ions, or Sb ions.

The N-type doping region is connected to a high potential during the operation of the photoelectric sensor. The majority carriers in the N-type doping region are electrons, and the concentration of free electrons is much greater than that of holes, thereby making the N-type doping region an area for accumulating electrons.

As the main region for generating and storing photo-generated carriers, the N-type doping region is located below the first protrusions 120, thereby effectively increasing the efficiency of photo-generated carrier generation on the N-type doping region, which is beneficial for improving the performance of the photoelectric sensor.

Returning to FIG. 9, a plurality of first protrusions are formed in the light-

receiving surface of the substrate in a pixel unit of the plurality of pixel units (S902), where both a lateral dimension and a vertical dimension of a first protrusion of the plurality of first protrusions are smaller than a wavelength of light. FIG. 6 shows a schematic cross-sectional view of a corresponding photoelectric sensor structure.

Referring to FIG. 6, a patterned substrate 100 is provided. Within the pixel unit 100a, a plurality of first protrusions 120 are formed on the light receiving surface 101 of the substrate 100. Both a lateral dimension d1 and a vertical dimension d2 of a first protrusion 120 are smaller than a wavelength of light.

The arrangement of the first protrusions 120 in the pixel unit 100a facilitates an increase in the optical transmittance of the photosensitive pixel region P and enhances the photoelectric conversion efficiency, thereby improving the optical sensitivity performance of the photoelectric sensor.

Specifically, the first protrusions 120 are positioned above the photoelectric elements, and grooves are formed between adjacent first protrusions 120. This may mitigate the refractive index change between air and the light receiving surface 101, reduce the high reflectivity caused by the abrupt refractive index change at the interface, thereby allowing more light to enter the photoelectric element and enhancing the transmittance of incident light. Moreover, by arranging the first protrusions 120 in the pixel unit 100a of the light receiving surface 101, it is also beneficial to disperse the incident light to multiple angles, increase the effective optical path of the light, and accordingly play a role in trapping light.

In one embodiment, since both the lateral dimension d1 and the vertical dimension d2 of the first protrusion 120 are smaller than the wavelength of light, the first protrusions 120 have almost no reflection of light when light is irradiated onto the light receiving surface 101. On the light receiving surface 101, light is more likely to regard the first protrusions 120 and a light-transmitting layer 300 between adjacent first protrusions 120 as the same substance. This may facilitate a reduction in light reflection loss, promote an increase in light transmission on the light receiving surface 101, effectively increase the number of transmitted photons and facilitate light signal collection, thereby enhancing the photoelectric detection efficiency.

In this disclosure, both the lateral dimension d1 and the vertical dimension d2 of the first protrusion 120 are smaller than the wavelength of light, which means that both the lateral dimension d1 and the vertical dimension d2 of the first protrusion 120 are smaller than the wavelength of light used by the photoelectric sensor in operation. The wavelength of light refers to the distance that the light wave travels within one oscillation cycle. Thus, when both the lateral dimension d1 and the vertical dimension d2 of the first protrusion 120 are smaller than the wavelength of light, the first protrusions 120 hardly reflect light, thereby reducing light reflection loss.

In one embodiment, in the step of forming the plurality of first protrusions 120 in the light-receiving surface 101 of the substrate 100, in the pixel unit 100a, the spacing d3 between adjacent first protrusions 120 is smaller than the wavelength of light.

Since the spacing d3 between adjacent first protrusions 120 is smaller than the wavelength of light, there is almost no reflection of light by the light-transmitting layer 300 between adjacent first protrusions 120 when light is irradiated onto the light-receiving surface 101. On the light-receiving surface 101, light is more likely to regard the first protrusions 120 and the light-transmitting layer 300 between adjacent first protrusions 120 as the same substance. This may facilitate a reduction in light reflection loss, promote an increase in light transmission on the light receiving surface 101, effectively increase the number of transmitted photons and facilitate light signal collection, thereby enhancing the photoelectric detection efficiency.

In one embodiment, in the step of forming the plurality of first protrusions 120 in the light-receiving surface 101 of the substrate 100, the lateral dimensions d1 of the first protrusion 120 gradually increase from top to bottom.

The lateral dimensions d1 of the first protrusion 120 gradually increase from top to bottom, which allows the film layer formed by the first protrusions 120 and the light-transmitting layer 300 between adjacent first protrusions 120 to be regarded as a layer-by-layer thin film with gradually changing refractive index. When light enters the substrate 100 through the light-receiving surface 101, a gentle and gradual refractive index change may be obtained, which greatly reduces the original high reflectivity caused by the abrupt refractive index change at the interface, so that more light may enter the photoelectric element, thus improving the transmittance of incident light and enhancing the anti-reflection effect.

In one embodiment, the shape of the first protrusion 120 is not limited. Specifically, as an example, in the step of forming the plurality of first protrusions 120 in the light-receiving surface 101 of the substrate 100, the shape of the first protrusion 120 includes a cylinder, a truncated cone, a prism, or a cuboid.

In one embodiment, in the step of forming the plurality of first protrusions 120 in the light-receiving surface 101 of the substrate 100, the plurality of first protrusions 120 are arranged in an array in the pixel unit 100a.

The plurality of first protrusions 120 are arranged in an array in the pixel unit 100a, which not only facilitates the design and layout, but also helps to maximize the number of the first protrusions 120 in a single pixel unit 100a, thereby further increasing the density of the first protrusions 120 and improving the uniformity of the film layer formed by the first protrusions 120 and the light-transmitting layer 300 between adjacent first protrusions 120.

In other embodiments, in the pixel unit, the first protrusions may not be arranged in an array. In the pixel unit, the first protrusions may also be arranged in other ways, such as scattered arrangement, staggered arrangement, or grid-like connection, etc.

Specifically, in one embodiment, the step of forming the plurality of first protrusions 120 in the light-receiving surface 101 of the substrate 100, includes: forming a mask layer on the light-receiving surface 101 and forming mask openings in the mask layer, where the mask openings are located in the plurality of pixel units 100a and exposing the light-receiving surface 101; and patterning the substrate 100 along the mask openings to form the plurality of first protrusions 120.

In one embodiment, a dry etching process is used to form the plurality of first protrusions 120 in the light-receiving surface 101 of the substrate 100.

The dry etching process has the characteristic of anisotropic etching. Therefore, by selecting the dry etching process, the etching is more directional, which is beneficial to improving the dimensional accuracy of the first protrusions 120.

In one embodiment, after forming the first protrusions 120, the step further includes removing the mask layer to expose the light-receiving surface 101.

In one embodiment, the step of patterning the substrate 100 further includes: forming a light-shielding groove 200 in the substrate 100 between adjacent pixel units 100a.

In one embodiment, one or more light-shielding grooves 200 may be formed in the substrate 100. For example, the first protrusions 120 and light-shielding groove(s) 200 may be formed simultaneously, or one after another, by patterning the substrate 100. The light-shielding groove 200 may be formed between adjacent pixel units 100a, as shown in FIG. 6.

The light-shielding groove 200 is used to provide a spatial location for the subsequent formation of a light-shielding structure.

Further, returning to FIG. 9, a light-transmitting layer is formed, where the light-transmitting layer covers the light-receiving surface of the substrate and fills between adjacent first protrusions (S903). FIG. 7 shows a schematic cross-sectional view of a corresponding photoelectric sensor structure.

Referring to FIG. 7, a light-transmitting layer 300 is formed. The light-transmitting layer 300 covers the light-receiving surface 101 of the substrate 100. And the light-transmitting layer 300 is also filled between adjacent first protrusions 120.

The light-transmitting layer 300 has light-transmitting properties. The light-transmitting layer 300 is formed on the light-receiving surface 101, so that light may enter the light-receiving surface 101 and the substrate 100 below through the light-transmitting layer 300, thus enabling the photoelectric element to function properly.

In one embodiment, the material of the light-transmitting layer 300 is a light-transmitting material, and the material of the light-transmitting layer 300 is an insulating material to prevent the electrical performance of the photoelectric sensor from being affected. The material of the light-transmitting layer 300 includes silicon dioxide, silicon nitride, silicon oxynitride, or silicon carbide. As an example, the material of the light-transmitting layer 300 is silicon dioxide. Silicon dioxide has high process compatibility, low cost, and excellent light-transmitting and insulating properties.

In one embodiment, the step of forming the light-transmitting layer 300, which covers the light-receiving surface 101 of the substrate 100, further includes: forming a light-shielding structure 210 in the light-shielding groove.

In one embodiment, a light-shielding structure 210 is formed in the light-shielding groove 200 between adjacent pixel units 100a, followed by forming the light-transmitting layer 300 to cover the light-receiving surface 101 of the substrate 100. A portion of the light-shielding structure 210 may be formed above a top surface of the first protrusions 120 and in the light-transmitting layer 300.

The light-shielding structure 210 is used to prevent optical crosstalk between adjacent pixels.

Specifically, the light-shielding structure 210 has a light-shielding effect and is located in the light-transmitting layer 300 between adjacent pixel units 100a. When incident light irradiates on the photosensitive pixel area P, the incident light only passes through the light-transmitting layer 300 to enter the corresponding pixel unit 100a, but the incident light fails to pass through the light-shielding structure 210 around the light-transmitting layer 300 to enter other adjacent pixel units 100a, thereby avoiding optical crosstalk with other pixel units 100a.

In one embodiment, the material of the light-shielding structure 210 is a conductive material. Conductive materials are typically opaque, thereby fulfilling the light-shielding function of the light-shielding structure 210.

As an example, the conductive material may be a metal material. Specifically, the material of the light-shielding structure 210 includes one or more of W, Al, Cu, Ti, TiN, Ta, and TaN. In one embodiment, the material of the light-shielding structure 210 is W.

In other embodiments, the conductive material may also be polysilicon doped with conductive ions.

Further, returning to FIG. 9, a plurality of second protrusions are formed over the light-transmitting layer (S904), where both a lateral dimension and a vertical dimension of a second protrusion of the plurality of second protrusions are smaller than a wavelength of light. FIG. 8 shows a schematic cross-sectional view of a corresponding photoelectric sensor structure.

Referring to FIG. 8, after forming the light-transmitting layer 300 covering light-receiving surface 101 of the substrate 100, the forming method further includes: patterning the light-transmitting layer 300 and forming a plurality of second protrusions 310 over the light-transmitting layer 300, where both a lateral dimension d4 and a vertical dimension d5 of a second protrusion 310 are smaller than the wavelength of light.

The second protrusions 310 contribute to enhancing the optical transmittance of the photosensitive pixel region P and increasing the photoelectric conversion efficiency, thereby improving the optical sensitivity performance of the photoelectric sensor. Moreover, the plurality of second protrusions 310 are arranged on the surface of the light-transmitting layer 300 and exhibit a repelling effect on water, thereby further aiding in avoiding moisture condensation on the surface of the light-transmitting layer 300 as much as possible.

Specifically, the second protrusions 310 are positioned above the photoelectric elements, and grooves are formed between adjacent second protrusions 310. This may alleviate the refractive index change between air and the surface of the light-transmitting layer 300, and reduce the high reflectivity caused by the abrupt refractive index change at the interface, thereby allowing more light to enter the light-transmitting layer 300 and increasing the transmittance of incident light.

In one embodiment, since the lateral dimension d4 and the vertical dimension d5 of the second protrusion 310 are both smaller than the wavelength of light, the second protrusions 310 hardly reflect light when light is irradiated onto the surface of the light-transmitting layer 300. On the surface of the light-transmitting layer 300, light is more likely to regard the second protrusions 310 and the light-transmitting layer 300 between adjacent second protrusions 310 as the same substance, which helps reduce light reflection loss, increase light transmission on the surface of the light-transmitting layer 300, effectively increase the number of transmitted photons, enhance light signal collection, and thereby improve the photoelectric detection efficiency.

In one embodiment, in the step of forming the plurality of second protrusions 310 over the light-transmitting layer 300, a spacing d6 between adjacent second protrusions 310 is smaller than the wavelength of light.

Since the spacing d6 between adjacent second protrusions 310 is smaller than the wavelength of light, light is more likely to regard the second protrusions 310 and the air between adjacent second protrusions 310 as the same substance when light is irradiated onto the light-transmitting layer 300. This is beneficial to further reduce light reflection loss, to increase the transmission of light on the light-transmitting layer 300, to effectively increase the number of transmitted photons, to increase the collection of light signals, and thereby to improve the photoelectric detection efficiency.

In one embodiment, in the step of forming the plurality of second protrusions 310 over the light-transmitting layer 300, the lateral dimensions d4 of the second protrusion 310 gradually increase from top to bottom.

Since the lateral dimensions d4 of the second protrusion 310 gradually increase from top to bottom, the film layer formed by the second protrusions 310 and the air between adjacent second protrusions 310 may be regarded as a layer-by-layer thin film with a gradual change in refractive index, thereby obtaining a smooth gradient of refractive index change when light enters the light-transmitting layer 300. This may significantly reduce the high reflectivity caused by the abrupt refractive index change at the interface, allow more light to enter the photoelectric element and increase the transmittance of incident light, thus enhancing the anti-reflection effect.

In one embodiment, the shape of the second protrusion 310 is not limited. Specifically, as an example, in the step of forming the plurality of second protrusions 310 over the light-transmitting layer 300, the shape of the second protrusion 310 includes a cylinder, a truncated cone, a prism, or a cuboid.

In one embodiment, in the step of forming the plurality of second protrusions 310 over the light-transmitting layer 300, the plurality of second protrusions 310 are arranged in an array.

The plurality of second protrusions 310 are arranged in an array, which is advantageous not only for the design and layout but also for maximizing the number of second protrusions 310, thereby further increasing the density of the second protrusions 310 and improving the uniformity of the film layer formed by the second protrusions 310 and air between adjacent second protrusions 310.

In other embodiments, the second protrusions may not be arranged in an array. The second protrusions may also be arranged in other ways, such as scattered arrangement, staggered arrangement, or grid-like connection, etc.

In this disclosure, a dry etching process is used for patterning the light-transmitting layer 300 and forming a plurality of second protrusions 310 over the light-transmitting layer 300.

The dry etching process has the characteristic of anisotropic etching. Therefore, by selecting the dry etching process, the etching is more directional, which is conducive to improving the size accuracy of the second protrusions 310.

Although the present disclosure is described above, it is not limited thereto. Various modifications and changes may be made by those skilled in the art without departing from the spirit and scope of the disclosure. Therefore, the scope of the present disclosure should be defined by the claims.

What is claimed is:

1. A photoelectric sensor, comprising:
a substrate, wherein the substrate has a light-receiving surface and comprises a plurality of photosensitive pixel regions, and each photosensitive pixel region comprises a plurality of pixel units arranged in a matrix, wherein
in a pixel unit of the plurality of pixel units, a plurality of first protrusions are formed in the light-receiving surface of the substrate, and
both a lateral dimension and a vertical dimension of a first protrusion of the plurality of first protrusions are smaller than a wavelength of light; and
a light-transmitting layer covering the light-receiving surface of the substrate and filling between adjacent first protrusions of the plurality of first protrusions.

2. The photoelectric sensor according to claim 1, wherein in each pixel unit, a spacing between the adjacent first protrusions of the plurality of first protrusions is smaller than the wavelength of light.

3. The photoelectric sensor according to claim 1, wherein in each pixel unit, the plurality of first protrusions are arranged in an array.

4. The photoelectric sensor according to claim 1, wherein a shape of the first protrusion comprises a cylinder, a truncated cone, a prism, or a cuboid.

5. The photoelectric sensor according to claim 1, wherein the lateral dimensions of the plurality of first protrusions gradually increase from top to bottom along a vertical direction.

6. The photoelectric sensor according to claim 1, wherein a plurality of second protrusions are formed over the light-transmitting layer, wherein both a lateral dimension and a vertical dimension of each second protrusion are smaller than the wavelength of light.

7. The photoelectric sensor according to claim 6, wherein a spacing between adjacent second protrusions of the plurality of second protrusions is smaller than the wavelength of light.

8. The photoelectric sensor according to claim 6, wherein the plurality of second protrusions are arranged in an array.

9. The photoelectric sensor according to claim 6, wherein a shape of the second protrusion comprises a cylinder, a truncated cone, a prism, or a cuboid.

10. The photoelectric sensor according to claim 6, wherein the lateral dimensions of the plurality of second protrusions gradually increase from top to bottom along a vertical direction.

11. The photoelectric sensor according to claim 1, further comprising: a light-shielding structure located in the substrate between adjacent pixel units of the plurality of pixel units.

12. The photoelectric sensor according to claim 1, wherein the photoelectric sensor is a backside illumination photoelectric sensor.

13. A method for forming a photoelectric sensor, comprising:
providing a substrate, wherein the substrate has a light-receiving surface and comprises a plurality of photosensitive pixel regions, and each photosensitive pixel region comprises a plurality of pixel units arranged in a matrix;
forming a plurality of first protrusions in the light-receiving surface of the substrate in a pixel unit of the plurality of pixel units, wherein both a lateral dimension and a vertical dimension of a first protrusion of the plurality of first protrusions are smaller than a wavelength of light; and
forming a light-transmitting layer covering the light-receiving surface of the substrate, wherein the light-transmitting layer fills between adjacent first protrusions of the plurality of first protrusions.

14. The method according to claim 13, wherein the plurality of first protrusions are formed having a spacing between adjacent first protrusions smaller than the wavelength of light.

15. The method according to claim 13, wherein the plurality of first protrusions are formed having the lateral dimensions increase from top to bottom along a vertical direction.

16. The method according to claim 13, wherein a dry etching process is used to form the plurality of first protrusions in the light-receiving surface of the substrate.

17. The method according to claim 13, wherein after forming the light-transmitting layer covering the light-receiving surface of the substrate, the method further comprises:
forming a plurality of second protrusions in a top surface of the light-transmitting layer by patterning the light-transmitting layer, wherein both a lateral dimension and a vertical dimension of each second protrusion of the plurality of second protrusions are smaller than the wavelength of light.

18. The method according to claim 17, wherein the plurality of second protrusions are formed having a spacing between adjacent second protrusions smaller than the wavelength of light.

19. The method according to claim 17, wherein the plurality of second protrusions are formed having lateral dimensions gradually increase from top to bottom along a vertical direction.

20. The method according to claim 13, wherein
forming the plurality of first protrusions in the light-receiving surface of the substrate comprises patterning the substrate;
patterning the substrate further comprises forming one or more light-shielding grooves in the substrate between adjacent pixel units of the plurality of pixel units; and
forming a light-shielding structure in each of the one or more light-shielding grooves, followed by forming the light transmitting layer covering the light receiving surface of the substrate.
